(19) United States
(12) Patent Application Publication
(10) Pub. No.: US 2016/0309627 A1
(43) Pub. Date: Oct. 20, 2016

(54) REVERSIBLE DOUBLE SIDED DNA-LAYERED PORTABLE LAMINATE MICROWAVE EMF SHIELD AND ABSORPTION DEVICE FOR TRANSFERABLE INSERTION INTO POCKETS

(71) Applicant: Harry V. Lehman, Novato, CA (US)

(72) Inventor: Harry V. Lehman, Novato, CA (US)

(21) Appl. No.: 15/187,625

(22) Filed: Jun. 20, 2016

Related U.S. Application Data
(63) Continuation-in-part of application No. 14/149,604, filed on Jan. 7, 2014.
(60) Provisional application No. 61/749,693, filed on Jan. 7, 2013.
(60) Provisional application No. 62/181,610, filed on Jun. 18, 2015.

(51) Int. Cl. H05K 9/00; A41D 27/20

(52) U.S. Cl. CPC H05K 9/0081; A41D 27/205; H05K 9/009

(57) ABSTRACT

A DNA material laden, EMF absorbing reversible device for a cellular phone that will both absorb and shield microwave energy, thereby reducing the microwave energy penetrating the tissues of the user.

### RELATED AND CO-PENDING APPLICATIONS

This application is a Continuation-In-Part of and claims priority to U.S. application Ser. No. 14/149,604 filed on 7 Jan. 2014 which claims priority to U.S. provisional application No. 61/749,693 filed on 7 Jan. 2013. The present application also claims priority benefit to U.S. Provisional Application No: 62/181,610 filed on 18 Jun. 2015.

### BACKGROUND

It is widely accepted, including by the cellular telephone manufacturers as demonstrated in their opening manuals, that were a particular cellular device is held, when in the ‘on’ condition, closer to the body than the approved proximity specifications for the same device, the level of microwave EMF absorbed by the body of the user of that device may exceed the governmentally-approved standards for approval of the device involved.

The wide acceptance that excessive proximity to an active cellular device may cause such a device is illustrated by the fact the all celluar devices sold in the United States are federally required to be sold with proximity-limit advisories in the operating manual for the device involved, whether the manual is in paper form on in digital form, sometimes difficult to find, but always present in lawfully sold devices in the United States and some other countries.

It is undisputed that cellular devices in the ‘on’ condition can radiate electromagnetic pulsations in the microwave frequencies and will always do so when in use for communication. It is also undisputed that close proximity to such cellular microwave broadcast will result over time in the heating of an adjacent fluid, including fluids in the human biological system, with the level of heating being both proximity variant (heat level over a given unit of time increasing with proximity) and time-variant (heat level at a given proximity increasing over time.)

The governmentally approved (including FCC) testing standards for power output levels for cellular microwave devices are based on the well-established fact that period-variant heating of fluids will result from close increased proximity of exposure to microwave signal from such devices.

A market currently exists for products which are claimed to mitigate the level of exposure to the human biological system from microwave cellular devices. A leading example of this market can be seen in the cellular holster market, where the holsters from major manufacturers in this field are typically made so that when the cellular device is in the holster, and the holster is mounted upon the person, such as by belt, the design of the holster keeps the cellular device a sufficient distance (typically between ⅝ of an inch and one inch) such that the approved proximity standards for the device involved are met.

Despite that direct contact between the cellular device and the body is common in the human population, the governmentally-sanctioned testing regimes allow for a power-output-variant distance from the liquid filled anthropomorphic human head models which are used for such testing, meaning that as radiated EMF power levels climb, the distance necessary to reach governmentally-sanctioned proximity limits will increase.

The relationship between near-field cellular microwave and the resulting heating of human liquids non-controversial, and as the currently available array of cellular holsters shows, a market exists for non-ionizing radiation mitigation instrumentalities based on these heat-standard concerns. In addition, cloth containing conductive threads in readily available and sold on the open market for the vendor-stated purpose of shielding the user of EMF generating devices from the non-ionizing radiation involved. For many years, despite some studies to the contrary, it is widely assumed in the electrical and electronic engineering communities that damage to living tissue could result only as a secondary result from the heating of the tissue involved by microwave, and not means other than damage from heat resulting from molecular vibration from the microwave agitation. The current and non-submitted and Claims apply to the lessening of the thermal effects which have for many decades been entirely accepted in the relevant engineering disciplines as resulting from microwave exposure as described above.

In the recent years, the new explosion of cellular devices onto the marketplace has encouraged recent peer-reviewed work which seeks to ascertain and/or to measure damage to living tissue from usage and physical exposure to cellular telephony. Numerous published studies have now documented potential adverse effects to human health including sperm die off, tumors (both benign and carcinogenic) DNA strand breakage, and collapse of the blood-brain barrier, and there exists a body of highly qualified study indicating that damage to animal tissue, including human tissue, may occur from microwave exposure where the mechanisms of harm are non-thermal, and the portable shielding technology here claimed will reduce signal level penetrating the body of its user, whether the concern of the user is with thermal damage, non-thermal damage, or a combination of such modalities.

In the light of the weight of these above-referenced studies and study undertaken at the WHO, the World Health Organization in 2011 classified cellular emissions as a Class 2B Possible Carcinogen. The following published studies provide exemplars of recent scientific work which has shed light on the effects of close-proximity cellular signal on the human biological system.

On cellular signal damage to the male reproductive system, see: Argawal, et al. “Pathophysiology of Cell Phone Radiation Oxidative Stress and Carcinogenesis with focus on Male Reproductive System” (2009). As a result of cell phone radiation exposure, this study documented DNA damage, cell death and infertility specifically as it relates to spermatoza. After observing noticeable damage due to non-thermal effects of RF electromagnetic exposure, the study recommends lowering the SAR (Specific Absorption Rate) for cell phones. The study can be found at this link http://www.ncbi.nlm.gov/pmc/articles/PMC2776019.

A 2015 study has further demonstrated cellular damage to human sperm, see Mathers, et al. “Effects of Mobile Phones on Sperm Quality” A systematic Review and Meta-Analysis”. Published in Environmental International, this study demonstrates that exposure to radio-frequency electromagnetic radiation from carrying cell phones in pant pockets negatively effects sperm quality. The study ruled out thermal effects due to proximity claiming that the results demonstrated non-thermal damage. Immediately below is a link to that study http://www.sciencedirect.com/science/article/pii/S0160412014001354.

Effects of cellular radiation have been shown as not been limited to testicular consequences. Rather, for example, breast cancers have been found to mimic the shape of cellular telephone held for long periods in the bra; see for example: West, Bailey et al. “Multifocal Breast Cancer in Young Women with Prolonged Contact between their Breasts and their Cegllular Phones”, (2013). This case study examined multi-focal invasive cancer discovered in young women between 21 and 39 years old. Characteristics of each case included smartphone placement in the bra against the breast for up to 10 hours per day. The tumors presented in the same area as the smartphone placement. With no prior family history of breast cancer, this study highlighted concern of overexposure to cellular radiation culminating in the potential for a cancer outcome. The authors stressed that consumers should keep cellular devices away from the body, here is a link to the study:

http://www.hindawi.com/journals/crim/2013/354682..

As recently as 2013, an edition of the prestigious journal Nature includes a Yale study led by a prominent professor at the Yale Medical School which detected neurological changes in rodent offspring where the mothers were exposed to cellular range EMF during pregnancy, see: Taylor, et al. “Fetal Radiofrequency Radiation Exposure from 800-1900 MHz—Rated Cellular Telephone Affects Neurodeveloment and Behaviour in Mice,”. This study used a control population group to compare outcomes in behaviour after cellular radiation exposure in utero. The results in the cellular exposed group demonstrated symptoms similar to ADHA after the offspring were interacting with their environment. See this link: http://www.nature.com/srep/2012/120315/srep00312/full/srep00312.html

Another 2013 study has shown indications of major health consequences from long term repetitive cellular telephone use, see Kesari, et al. “Cell Phone Radiation Exposure on Brain and Associated Biological Systems,”. Health issues reported to be associated with RF exposure include: childhood leukemia, brain tumors, genotoxic effects, neurological effects, neurodegenerative diseases, immune system deregulation, allergic and inflammatory responses, infertility and some cardiovascular effects. Study conclusions: regular and long-term use of RF http://www.ncbi.nlm.nih.gov/pubmed/23678539

As these studies suggest, a growing body of research is demonstrating the need for cell phone users to take protective measures against emission exposure to the body. With the growth in cellular usage as a primary communication tool, the potential for over-exposure to RF microwave emissions is now more enhanced than ever. Usage of barrier material which mitigates the seepage of emissions towards the human body will provide a form of protection from over-exposure to prolonged microwave broadcast. As the Argawal et al study, supra, indicates, there is a direct negative impact on sperm survival and sperm quality from the carriage of cellular devices in the front pants pockets. Consequently a pad which can be conveniently inserted into the pocket and has an EMF absorbing and blocking character will provide a useful and saleable product to the market of persons concerned to reduce EMF exposure.

In a Feb. 8, 2013 letter to the Los Angeles Unified School District authored by Dr. Martha Herbert, M.D. Ph.D, a pediatric neurologist from the faculty of The Harvard Medical School who practices in pediatric neurology at Massachusetts General Hospital, which letter is attached as Exhibit A hereto after the Clams and Diagrams, herein, Dr. Herbert notes that: “in fact, there are thousands of papers that have accumulated over decades—and are now accumulating at an accelerating pace, as our ability to measure impacts become more sensitive—that document adverse health and neurological impacts of EMF/RFR.”

The expanding body of peer-reviewed and credible research on EMF and living tissue shows that in addition to affected living tissue involved by molecular vibration resulting in heat (and thermal damage) in fact living tissue absorbs microwave EMF. Thus while being affected by it, DNA-containing tissue absorbs EMF, and necessarily, through doing so, reduces the level of EMF reaching areas on the downstream side of the EMF stream from the DNA materials which have absorbed EMF signal en route.

Some recent work, such as shown in a March 2012 article by Dr. Andrew Galsworthy titled The Biological Effects of Weak Electromagnetic Fields indicates mechanisms through which DNA can be affected through the absorption of microwave EMF. As Dr. Galsworthy reports, many of the reported biological effects of non-ionizing electromagnetic fields occur at levels too low to cause significant heating: i.e. they are non-thermal. As the referenced March 2012 Galsworthy paper states, as to EMF effects: Most of them can be accounted for by electrical effects on living cells and their membranes. The alternating fields generate alternating electric currents that flow through cells and tissues and remove structurally-important calcium ions from cell membranes, which then makes them leak.” Thus, as illuminated by Dr. Herbert's attached letter, thousands of credible papers show that DNA containing tissues absorb microwave EMF.

Each of the above studies indicates that living tissue absorbs microwave EMF with biological effect. The purpose of the instant disclosed subject matter is to use the EMF absorption characteristics of organic materials, meaning material which contain DNA, integrated into an absorbing pad, primarily for pocket or bra insertion, as a means of reducing the level of EMF which would otherwise penetrate the body of the cellular user in the absence of the use of the disclosed subject matter.

While the Specific Absorption Rate, one standard by which cellular microwave absorption by the body is commonly measured, is typically based upon a penetration through an inert emulation of a human head, competent experimental work indicates that the level of absorption in living tissue is man times greater than the level of microwave absorption through an inert liquid, such as water. Thus in a 1983 article entitled An Optical Method for Investigating the Microwave Characteristics of DNA and other Biomolecules in Solution by Mays L. Swicord and Christopher C. Davis, published in the journal Bioelectromagnetics experimental results were reporting which determined that: “A significant increase in the absorption of DNA solutions as compared with pure water has been observed that is consistent with microwave absorption by the longitudinal mode of the double helix” Thus, in their conclusion, Swicord and Davis state that: “However the results presented this work are in good agreement with the Prohofsky model acoustic mode absorption by varying lengths of DNA. Prohofsky and Van Zandt predicted that 450 to 2000 base pair of segments of synthetic DNA should absorb 10³ to 10⁴ timesas strongly in the microwave region as an equivalent mass of water with a decrease in peak absorption due to water damping. The 1.7% dilution of DNA investigated by PFLOH spectroscopy in this work indicated a 40% increase in absorption above pure water at 8 GHz and at 10 to 12% increase at 12 GHz. The measured DC conductance of this DNA sample was quite low yet its absorption of the DNA solution does not come from iconic behaviour. The observed absorption is suggestive of direct microwave absorption by the longitudinal acoustic mode of the double helix discussed by Prohofsky and co-workers. Based on the concentration of the DNA solution which gave 40% more absorption than pure water at 8 GHz, the microwave absorption at this frequency is 24 times greater than an equivalent mass of water” Dr. Swicord, one of the two lead researchers (who, after a working at FDA spent much of the rest of his career in prestigious work at Motorola) later personally questioned whether the University of Maryland studying findings of the 24-fold increase in Specific Absorption Rate from the presence of DNA salts had been replicated. Regardless of whether level of specific absorption in DNA solution is precisely 24 times the level of specific absorption from non-DNA solution water, this University of Maryland study is precisely cumulative with the cumulative with the many other studies referenced herein which demonstrate that DNA-containing materials absorb microwave EMF.

Many examples of microwave-absorbing or deflecting items of clothing exist in the market and the fact that clothe woven with conducive wire can imbue that clothing (and the piece of claim made from it) with EMF-resistant characteristics is well established. Numerious examples exist of cloth or woven metal sold for the purpose of fabricating EMF resistant items of clothing, and for permanent modification to clothing (such as by EMF-resistant head-adhesive patches) some such examples associated with claims of proprietary right and others a general sense and as a matter of scientific principle within the public domain. Claim 1 below, is for the first readily-garment-transferable durable pocket shield for use in mitigating and reducing the level of microwave EMF which reaches the human biological system due to the placement of a cellular device in a pocket or other clothing.

Additionally, the instate disclosed subject matter is the first to combine the EMF-absorbing characteristics of DNA-rich materials, including but not limited to conductive woven materials, in a shaped pad for insertion in the pocket (or other clothing) between the EMF source (the cellular device) and the body in order to mitigate the level of microwave EMF absorption by the body involved. This is portable protection.

This DNA layer(s) laminate microwave EMF shield is for insertion in any pocket for the purpose of mitigation of the penetration of cellular telephone EMF when the device is carried on the person of the end user. In the preferred laminate embodiment, the working of the reversible device is three-fold based upon the differing layers of its composition: 1) An exterior layer of high-DNA content material (including but not limited to leather) absorbs microwave EMF signal, the: 2) an enclosed or “sandwiched” layer of EMF barrier material (including by not limited to copper screen or sliver-thread cloth, or dielectric-impregnated mylar or other plastic) serves to block microwave EMF and then: 3) the last high-DNA content layer, by absorption, reduces the any remaining level of microwave EMF which may have penetrated through the prior two layers of this reversible device. (prior in relation to proximity to source).

### BRIEF DESCRIPTION OF THE DRAWINGS

FIG. 1 hereto shows an expandable view of the here-submitted multiple layered, reversible, portable and garment-transferable EMF absorbing and EMF shielding pocket and clothing device. This figure shows two exterior high-DNA content layers (for example leather), 10, which are EMF absorbing, along with an interior layer of EMF-shielding material placed between the two DNA containing layers. In this Figure the EMF-shielding interior layer, 12, is noted as a FARADAY LAYER or RF shielding nickel-copper or silver fabric or RF-shielding dielectric).

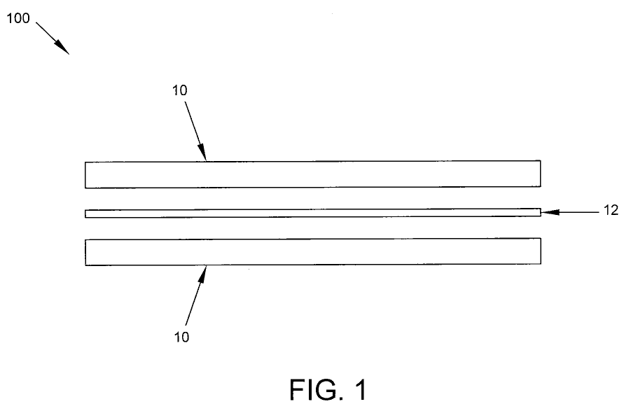

FIG. 2 hereto shows an assembled device, composed of the components indicated in FIG. 1, with the three layers held together in the pocket insertable format by circumferential stitching, aspect 14, which binds all three layers together. This figure also shows the Greater EMF, 16, prior to passing through the unit and the reduced or less EMF, 17, after passing through the unit (for example leather).

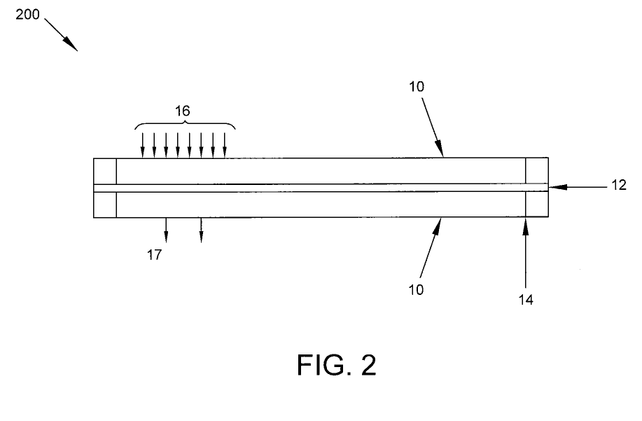

FIG. 3 hereto shows a cellular phone, 300, laid over the disclosed subject matter with rounded corners, 20, such that if the cellular device is radiating EMF, said EMF will be absorbed, then blocked, and then any remainder further absorbed by this multiple level of DNA and EMF layers 18. The wedge shape aids entry into pocket, purse or bra.

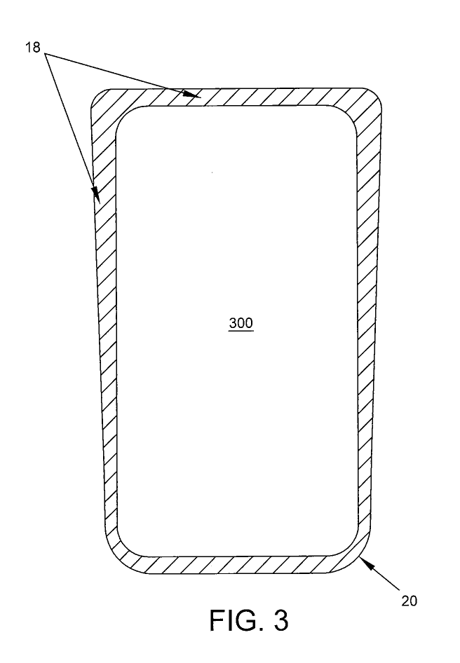

FIG. 4 hereto shows the disclosed subject matter in an emulation of actual use, the bottom, 500, thereby illustrating the presence of a cellular telephone, then the disclosed subject matter (comprised of a DNA-rich layer, then an EMF-shielding layer, then another and final EMF-absorbing layer), then a layer of clothing (the interior pocket liner) and then living human tissue, 600.

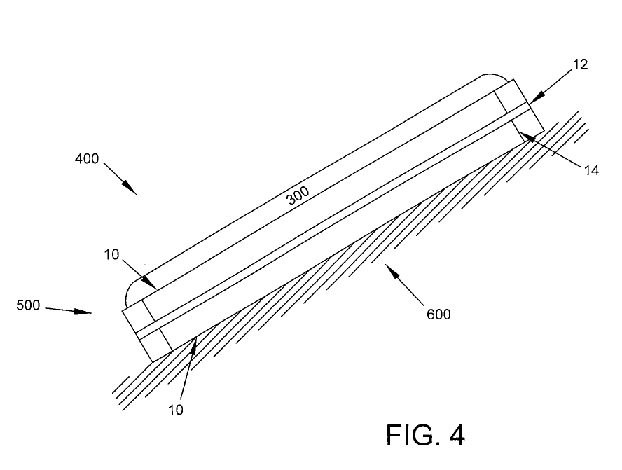

And aspect of this disclosure is disclosed subject matter for a for a pocket-insertion-capable microwave shielding device, which can be moved at the owner's choice from one garment to another garment without attachment to the garment by adhesive or mechanical means and which reduces the level of EMF absorbed by the bod of the user of said here-claimed device.

An aspect of this disclosure is disclosed subject matter for a pocket-insertion-capable microwave absorbing device, which can be moved at the owners choice from one garment to another garment and without attachment to the garment by adhesive or mechanical means, which reduces the level of EMF reaching the biological system of the end user.

An aspect of this disclosure is disclosed subject matter for an article of clothing which has employed DNA laden material, including naturally occurring DNA-rich material such as leather or vegetable fiber but including any other materials which have been impregnated with DNA by manufacture, including but not limited to through soaking in DNA-salt brine for the absorption of EMF so that the energy level of the EMF reaching the end user is reduced thereby.

An aspect of this disclosure is disclosed subject matter for a pocket-insertion-capable microwave absorbing and shielding (or blocking) device, which through the use of both DNA based absorbing layers and EMF shielding layers provides the end-user with both DNA-based absorption of microwave, and shielding of the end user from microwave in a single device which can be moved at the owner's choice from one garment to another garment and without attachment to the garment by adhesive or mechanical means.

An aspect of this disclosure is disclosed subject matter for an EMF-shielding device which through use of a wedged shape, with the narrow end of the shape, with the narrow end of the shape to lead insertion into the pocket or other article of clothing, so that the insertion of said EMF-shielding device is made easier by such shape as opposed to rectangular devices of similar purpose or a device with a wider wend facing the pocket.

An aspect of this disclosure is disclosed subject matter for an EMF absorbing device, including by DNA enrichment thereof, which through the use of a wedged shape, with the narrow end of the shape to lead insertion into the pocket or other article of clothing, so that the insertion of said EMF shielding device, which device uses conductive or dielectric materials, is made easier to insert in clothing by such wedge shape as opposed other shapes which do not employ a narrower leading edge.

An aspect of this disclosure is for disclosed subject matter for an EMF absorbing device, including by DNA enrichment thereof, which device also integrates a layer or layers of EMF shielding, by conductive or dielectric means, which through the use of a wedged shape, with the narrow end of the shape to lead insertion into the pocket or other article of clothing, so that the insertion of said EMF shielding device is made easier by such shape as opposed to other shapes which do not employ a narrower leading edge.

An aspect of this disclosure is for disclosed subject matter for an EMF shielding device which through the use of rounded corners the insertion of said EMF shielding device is made easier by such shape as opposed to right angle corners.

An aspect of this disclosure is disclosed subject matter for an EMF shielding by conductive layer or dielectric layer, which through the use of rounded corners the insertion of said EMF absorbing device is made easier by such shape as opposed to right angle corners.

An aspect of this disclosure is disclosed subject matter for a reversible multiple layered EMF absorbing and EMF shielding device which will operated to both absorb and shield microwave energy, regardless of which side of the device is presented to the tissues of the end-user of the device, when the device is used in company with a microwave source.

An aspect of this disclosure is disclosed subject matter for a reversible multiple layered EMF absorbing and EMF shielding device which will operated to both absorb and shield microwave energy, regardless of which side of the device is presented to the microwave source and in the alternative regardless of which side of the device is presented to the tissues of the end-user of the device, and where microwave energy which has not been fully blocked by the shielding layer, such that microwave energy which has penetrated through the two layers closest to the microwave source will be absorbed in all or part by the third and DNA content layer of the device.

DNA material, DNA content layers and DNA rich layers are used to denote materials or layers containing DNA.

1. An article of clothing comprising a naturally DNA laden material including but not limited to leather or vegetable fiber and an EMF shielding conductive or dielectric layers, each layer thereby reducing the level of EMF reaching the user.

2. The article of clothing according to claim 1 which can be moved at the owner's choice from one garment to another without attachment to the garment by adhesive or mechanical means.

3. The article of clothing according to claim 1 with a wedged shape and narrow end to lead insertion into the pocket or other article of clothing making insertion of the device easier.

4. The article of clothing according to claim 1 with a wedged shape and narrow end to lead insertion into the pocket or other article of clothing making insertion of the device easier through the use of rounded corners.

5. The article of clothing according to claim 1, where the article is reversible.
